(19) United States
(12) Patent Application Publication
(10) Pub. No.: US 2011/0042693 A1
(43) Pub. Date: Feb. 24, 2011

(54) SEMICONDUCTOR DEVICE AND MANUFACTURING METHOD THEREOF

(75) Inventors: Kenshi Tada, Osaka (JP); Yutaka Takafuji, Osaka (JP); Yasumori Fukushima, Osaka (JP); Kazuhide Tomiyasu, Osaka (JP); Michiko Takei, Osaka (JP); Kazuo Nakagawa, Osaka (JP); Shin Matsumoto, Osaka (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA, Osaka-shi, Osaka (JP)

(21) Appl. No.: 12/933,042

(22) PCT Filed: Apr. 9, 2009
(86) PCT No.: PCT/JP2009/001650

§ 371 Date: Sep. 16, 2010

(30) Foreign Application Priority Data
May 28, 2008 (JP) 2008-139754

(51) Int. Cl. H01L 33/08; H01L 21/762

(52) U.S. Cl. 257/88; 438/458; 257/E33.002; 257/E21.568

(57) ABSTRACT

A semiconductor device (10) includes a support substrate (14), an adhered device part (11) adhered to the support substrate (14), a multilayer device part (13) stacked on the adhered device part (11), and an adjacent device part (12) formed in a region adjacent to the adhered device part on the support substrate (14). The adhered device part (11), the multilayer device part (13), and the adjacent device part (12) are electrically connected to one another.

### TECHNICAL FIELD

The present invention relates to semiconductor devices and methods for manufacturing the same.

### BACKGROUND ART

In recent years, so-called active matrix driving devices have been known in which thin-film transistors (TFTs) including amorphous silicon (amorphous Si: a-Si) and polysilicon (poly-Si: p-Si) are formed on given substrates including glass substrates and quartz substrates larger than Si wafers to drive liquid crystal display panels, organic EL panels, and the like. Moreover, in order to integrate systems requiring higher performance such as peripheral drivers, or memories, microprocessors, image processors, and timing controllers onto substrates, it has been studied to form Si devices having higher performance.

In particular, attention has been drawn to integration of peripheral drivers by using poly-Si allowing a high mobility and thus high-speed operation. However, poly-Si includes localized levels within a band gap due to the imperfection of crystallinity, and defects and localized levels near grain boundaries. Thus, the poly-Si has problems such as mobility degradation, an increase in S coefficient (subthreshold coefficient), and the like.

Moreover, when TFTs are formed on substrates such as glass substrates whose process accuracy is lower than that of processes on Si wafers, miniaturization of devices to be formed is limited by the relatively low process accuracy. Thus, it is difficult to integrate systems such as memories, microprocessors, image processors, and timing controllers which require device parts having higher performance onto the glass substrates.

To address these problems, Patent Document 1, for example, discloses a technique in which a device part including a single crystal Si thin-film transistor formed on a silicon substrate is adhered on, for example, a glass substrate. That is, in Patent Document 1, the device part including the single crystal Si thin-film transistor on a surface side of the silicon substrate, and a hydrogen ion implantation layer having a peak position of the distribution of hydrogen ions are formed on the silicon substrate, and the silicon substrate is bonded to, for example, a glass substrate such that the surface side of the silicon substrate on which the device part is formed is disposed on the glass substrate with an adhesive layer interposed therebetween.

Then, a thermal process is performed to strip part of the silicon substrate along the hydrogen ion implantation layer, thereby removing an unnecessary part of the silicon substrate. After that, the thickness of a silicon layer of the device part provided with the single crystal Si thin-film transistor is controlled by etching in a glass substrate direction, thereby completing the adhesion process. This method enables a device part having high performance to be integrated on a glass substrate.

Moreover, in Patent Document 2, a semiconductor layer is formed on a single crystal silicon substrate with an underlayer insulating film interposed therebetween, and an adhesion device is formed on the semiconductor layer, and then a support substrate is adhered to the adhesion device. After that, a back surface of the single crystal silicon substrate is polished, and a multilayer device is formed on a single crystal silicon substrate layer remaining over the adhesion device, thereby manufacturing a multilayer-type semiconductor device having high integration.

### CITATION LIST

### Patent Document

PATENT DOCUMENT 1: Japanese Patent Publication No. 2004-165600

PATENT DOCUMENT 2: Japanese Patent Publication No. H4-196264

### SUMMARY OF THE INVENTION

### Technical Problem

However, in the method of Patent Document 1, the region on the adhesion device can be used only for interconnects, and the integration degree is limited due to the alignment precision in the adhesion process. For this reason, it is difficult to integrate a low voltage logic circuit, a stable analog circuit, a high-voltage drive circuit, etc. at a high degree onto a glass substrate, a quartz substrate, or the like.

Moreover, in the method of Patent Document 2, the support substrate is adhered to the adhesion device, and then the back surface of the single crystal silicon substrate is polished. Thus, particularly in the case where the support substrate is a glass substrate, a quartz substrate, or the like, it becomes difficult to use the method of Patent Document 2.

The present invention was devised in view of the problems. It is a main object of the present invention to provide a satisfactory display device in which a low-voltage logic circuit, a stable analog circuit, a high-voltage drive circuit, and the like are integrated at a high degree on a given substrate such as a glass substrate or a quartz substrate larger than a silicon substrate to satisfactorily reduce the area of a semiconductor device.

### Solution to the Problem

A semiconductor device according to the present invention includes: a support substrate; an adhered device part adhered to the support substrate; a multilayer device part stacked on the adhered device part; and an adjacent device part formed in a region adjacent to the adhered device part on the support substrate, wherein the adhered device part, the multilayer device part, and the adjacent device part are electrically connected to one another.

Moreover, in the semiconductor device according to the present invention, the support substrate may have an area larger than that of the adhered device part.

Moreover, in the semiconductor device according to the present invention, the adjacent device part may be formed close to the adhered device part.

Moreover, in the semiconductor device according to the present invention, the support substrate may be made of glass, quartz, or plastic.

Moreover, in the semiconductor device according to the present invention, the adjacent device part may be made of polysilicon or amorphous silicon.

Moreover, in the semiconductor device according to the present invention, the adhered device part may be made of single crystal silicon or polysilicon.

Moreover, in the semiconductor device according to the present invention, the multilayer device part may be made of single crystal silicon, polysilicon, or amorphous silicon.

Moreover, in the semiconductor device according to the present invention, the adhered device part may include a BOX layer, and the adhered device part and the multilayer device part may be isolated from each other by the BOX layer.

Moreover, in the semiconductor device according to the present invention may further include an active matrix region, wherein the multilayer device part or the adjacent device part may be at least a part of the active matrix region.

Moreover, in the semiconductor device according to the present invention may further include an active matrix region, wherein the multilayer device part or the adjacent device part may be at least a part of a drive circuit in the active matrix region.

Moreover, in the semiconductor device according to the present invention, the active matrix region may include a liquid crystal display region or an EL display region.

A method for manufacturing a semiconductor device according to the present invention includes: a device formation process for forming a device in an SOI substrate including an insulating layer, a semiconductor layer, and a substrate layer, the insulating layer being sandwiched between the semiconductor layer and the substrate layer, and the device including the semiconductor layer; an adjacent device part formation process for forming an adjacent device part on a support substrate; a process for forming a hydrogen ion implantation region in the substrate layer; an adhesion process for adhering the SOI substrate provided with the device to the support substrate provided with the adjacent device part such that the device faces the support substrate; an adhered device part formation process for forming an adhered device part including the device by removing at least part of the substrate layer from the SOI substrate adhered to the support substrate by a thermal process along the hydrogen ion implantation region, and then by performing an etching process; a multilayer device part formation process for forming a multilayer device part by using the substrate layer remaining after the removal as at least a layer of semiconductor layers; and a connection process for electrically connecting the adjacent device part, the adhered device part, and the multilayer device part to one another.

A method for manufacturing a semiconductor device according to the present invention includes: a device formation process for forming a device in an SOI substrate including an insulating layer, a semiconductor layer, and a substrate layer, the insulating layer being sandwiched between the semiconductor layer and the substrate layer, and the device including the semiconductor layer; a process for forming a hydrogen ion implantation region in the substrate layer; an adhesion process for adhering the SOI substrate provided with the device to a support substrate such that the device faces the support substrate; an adhered device part formation process for forming an adhered device part including the device by removing the substrate layer from the SOI substrate adhered to the support substrate by a thermal process along the hydrogen ion implantation region, and then by performing an etching process; a multilayer device part formation process for forming a multilayer device part on the adhered device part; an adjacent device part formation process for forming an adjacent device part on the support substrate such that the adjacent device part is adjacent to the adhered device part; and a connection process for electrically connecting the adjacent device part, the adhered device part, and the multilayer device part to one another.

A method for manufacturing a semiconductor device according to the present invention includes: a device formation process for forming a device in a silicon substrate including a semiconductor layer and a substrate layer; a process for forming a hydrogen ion implantation region in the substrate layer; an adhesion process for adhering the silicon substrate provided with the device to a support substrate such that the device faces the support substrate; an adhered device part formation process for forming an adhered device part by removing an excess silicon layer from the silicon substrate adhered to the support substrate by a thermal process along the hydrogen ion implantation region, and then by performing an etching process to adjust a thickness of the silicon layer in a region provided with the device; a multilayer device part formation process for forming an insulating layer covering the silicon substrate, and forming an multilayer device part on the insulating layer; an adjacent device part formation process for forming an adjacent device part on the support substrate such that the adjacent device part is adjacent to the adhered device part; and a connection process for electrically connecting the adjacent device part, the adhered device part, and the multilayer device part to one another.

Moreover, in the method for manufacturing the semiconductor device according to the present invention, the silicon layer may be adjusted to have a thickness of 10-500 nm in the adhered device part formation process.

### ADVANTAGES OF THE INVENTION

According to the present invention, the integration degree of the devices can be increased, and the area of the semiconductor device can satisfactorily be reduced.

### BRIEF DESCRIPTION OF THE DRAWINGS

FIG. 1 is a cross-sectional view of a semiconductor device according to a first embodiment.

FIG. 2A is a cross-sectional view of an SOI substrate according to the first embodiment. FIG. 2B is a cross-sectional view of an SOI substrate when a hydrogen ion implantation region is formed without providing a mask.

FIG. 3 is a cross-sectional view of an adjacent device part, an adhered device part, and a multilayer device part according to the first embodiment.

FIG. 4 is a cross-sectional view of a semiconductor device according to a second embodiment.

FIG. 5 is a cross-sectional view of an adhered device part of the second embodiment.

FIG. 6 is a cross-sectional view of an adjacent device part, the adhered device part, and a multilayer device part of the second embodiment.

FIG. 7 is a cross-sectional view of a display device according to a third embodiment.

FIG. 8 is a cross-sectional view of a display device according to a fourth embodiment.

### DESCRIPTION OF REFERENCE CHARACTERS

10, 60 Semiconductor Device
11, 61 Adhered Device Part
12, 62 Adjacent Device Part
13, 63 Multilayer device part
14, 64 Support Substrate
15, 65 Insulating Layer
19, 20, 38, 40, 69, 70, 88, 90 Metal Interconnect
16, 36, 46, 66, 86, 96 TFT
110, 120 Display Device
18, 157 BOX Layer
37, 87 Passivation Film

### DESCRIPTION OF EMBODIMENTS

Embodiments of the present invention will be described in detail below with reference to the drawings. Note that the present invention is not limited to the embodiments below.

### First Embodiment

### Configuration of Semiconductor Device 10

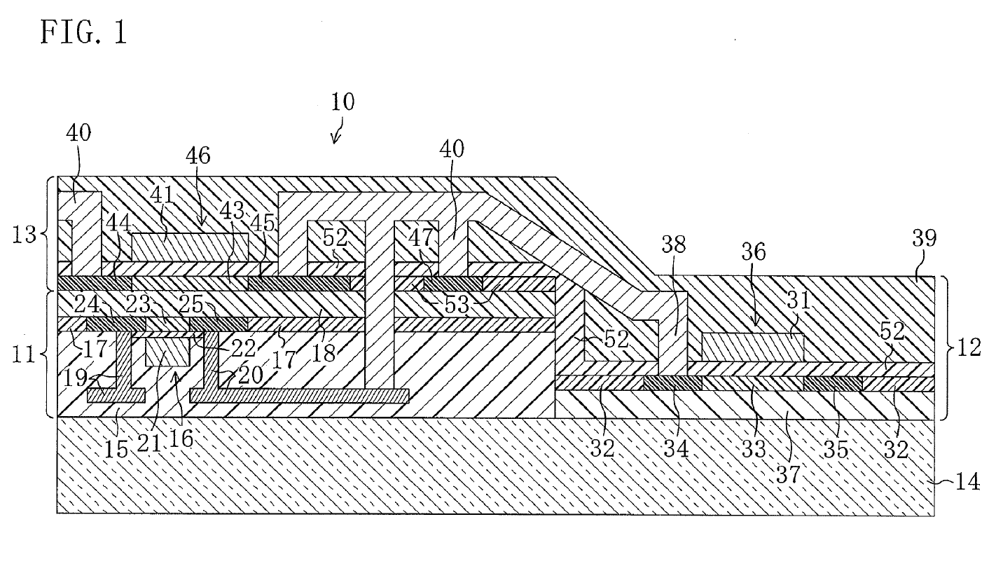

FIG. 1 is a cross-sectional view schematically illustrating main components of a semiconductor device 10 according to a first embodiment of the present invention. The semiconductor device 10 includes a support substrate 14, an adhered device part 11, a multilayer device part 13, and an adjacent device part 12.

The support substrate 14 is made of glass, quartz, plastic, or the like. Moreover, the support substrate 14 has an area larger than that of the adhered device part 11.

The adhered device part 11 is adhered on the support substrate 14. The adhered device part 11 includes an insulating layer 15 provided on the support substrate 14, a TFT 16 provided on the insulating layer 15, and a BOX layer (insulating layer) 18 provided on the TFT 16, thereby implementing a low-voltage circuit.

The TFT 16 includes an active layer, a gate insulating film 22 provided on the active layer, and a gate electrode 21 provided on the gate insulating film 22.

The active layer is made of single crystal silicon or polysilicon, and includes a channel region 23, a source region 24, and a drain region 25.

Metal interconnects 19, 20 are formed in the insulating layer 15. The metal interconnects 19, 20 are electrically connected to the source region 24 and the drain region 25, respectively of the TFT 16.

The multilayer device part 13 is stacked on the adhered device part 11. The multilayer device part 13 includes a semiconductor layer, a device isolation layer 53, and a TFT 46 provided on the BOX layer 18 of the adhered device part 11, and an interlayer insulating film 39 covering the TFT 46, thereby implementing a high-voltage circuit.

The TFT 46 includes an active layer, a gate insulating film 52 provided on the active layer, and a gate electrode 41 provided on the gate insulating film 52.

The active layer is made of single crystal silicon, and includes a channel region 43, a source region 44, a drain region 45, and a high concentration impurity region 47.

Metal interconnects 40 electrically connected to the source region 44 and the drain region 45 of the TFT 46 are formed in the interlayer insulating film 39. The metal interconnect 40 connected to the drain region 45 of the multilayer device part 13 reaches the metal interconnect 20 of the adhered device part 11 provided under the multilayer device part 13, and is electrically connected to the metal interconnect 20.

The adjacent device part 12 is formed in a region adjacent to the adhered device part 11 on the support substrate 14. The adjacent device part 12 includes a passivation film 37 provided on the support substrate 14, a device isolation layer 32 and a TFT 36 provided on the passivation film 37, and the interlayer insulating film 39 covering the TFT 36, thereby implementing a high-voltage circuit. Moreover, the adjacent device part 12 is formed close to the adhered device part 11.

The TFT 36 includes an active layer, a gate insulating film 52 provided on the active layer, and a gate electrode 31 provided on the gate insulating film 52.

The active layer is made of single crystal silicon, polysilicon, or amorphous silicon, and includes a channel region 33, a source region 34, and a drain region 35.

A metal interconnect 38 is formed in the interlayer insulating film 39. The metal interconnect 38 is electrically connected to the source region 34 and the drain region 35 of the TFT 36. The metal interconnect 38 of the adjacent device part 12 is electrically connected to the metal interconnect 20 of the adhered device part 11 and the metal interconnect 40 of the multilayer device part 13.

—Method for Manufacturing Semiconductor Device 10—

Next, a method for manufacturing the semiconductor device 10 according to the first embodiment of the present invention will be described.

(Adjacent Device Part Formation Process)

First, a support substrate 14 is prepared. An adjacent device part 12 is formed such that the adjacent device part 12 is adjacent to an adhered device part formation region of the support substrate 14.

To form the adjacent device part 12, a passivation film 37 is first formed on the support substrate 14. Subsequently, a semiconductor layer such as a TFT 36 is patterned by photolithography on the passivation film 37.

Next, a mask is formed on a portion of the semiconductor layer which corresponds to a position where a channel region is to be formed, and ions of an impurity element are implanted to form a channel region 33 in the semiconductor layer.

Subsequently, a gate insulating film 52 and a device isolation layer 32 are formed on the semiconductor layer. Then, a gate electrode 31 is patterned by photolithography on the gate insulating film 52 so that the gate electrode 31 corresponds to the channel region 33 under the gate insulating film 52. Next, impurity regions (a source region 34 and a drain region 35) are formed, thereby fabricating the TFT 36.

The TFT 36 is covered with an interlayer insulating film 39 as described below to complete the adjacent device part 12.

(Adhered Device Part Formation Process)

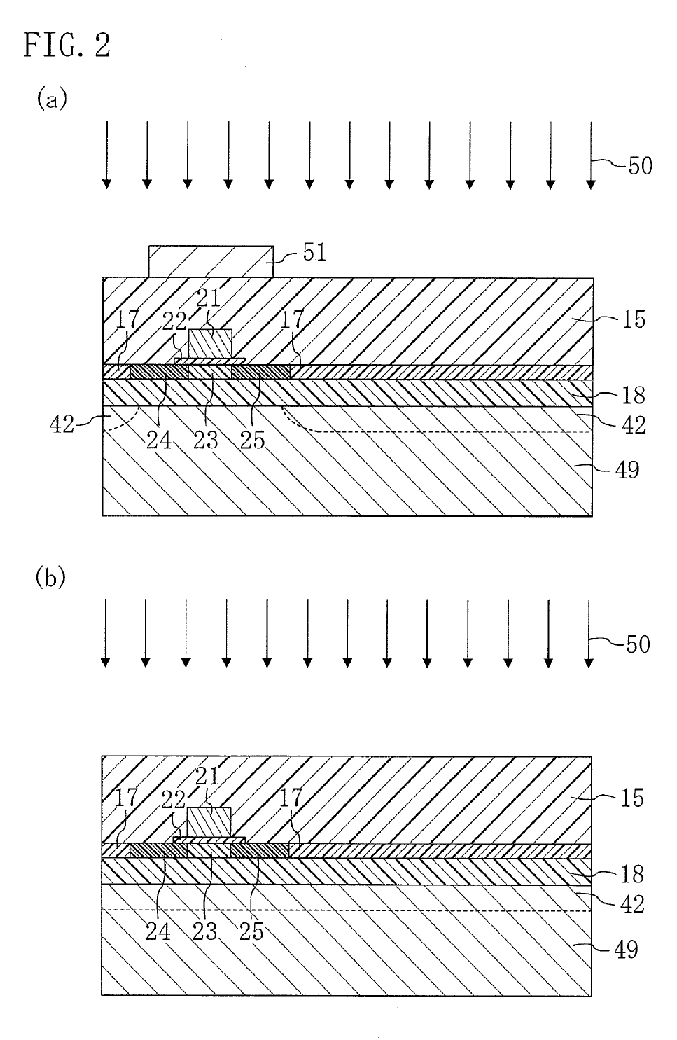

Next, a device which will be adhered to the support substrate 14 is fabricated in a process separated from the adjacent device part formation process. That is, an SOI substrate (silicon substrate) including an insulating layer (a BOX layer 18), a semiconductor layer, and a substrate layer 49 is first prepared as illustrated in FIG. 2A. The insulating layer is sandwiched between the semiconductor layer and the substrate layer 49. The semiconductor layer and the substrate layer 49 each include a silicon layer.

Next, the semiconductor layer of the SOI substrate is patterned to form a gate insulating film 22 and a device isolation layer 17. Ions of an impurity element are implanted into the semiconductor layer to form an active layer including a channel region 23.

Subsequently, a gate electrode 21 is patterned on a region of the gate insulating film 22, the region corresponding to the channel region 23. Moreover, a source region 24 and a drain region 25 are formed by ion implantation of impurities, thereby forming a TFT 16.

Next, an insulating layer 15 is formed on a side of the SOI substrate where the TFT 16 is provided. Subsequently, a mask 51 is formed in a region on the insulating layer 15, the region corresponding to the active layer of the TFT 16.

Next, hydrogen ions 50 are implanted into the SOI substrate from a side of the SOI substrate where the mask 51 is provided on the insulating layer 15, thereby forming a hydrogen ion implantation region 42 in the substrate layer 49.

Note that here, as illustrated in FIG. 2B, the hydrogen ion implantation region 42 may be formed in the substrate layer 49 without forming the mask 51. In this case, it is possible to increase the area of the semiconductor layer which is used for a multilayer device part formation process.

Subsequently, the mask 51 is removed. Contact holes reaching the source region 24 and the drain region 25, respectively of the TFT 16 are formed in the insulating layer 15. Then, metal interconnects 19, 20 are formed in the contact holes. Moreover, the metal interconnects 19, 20 are patterned to extend on the insulating layer 15.

Next, to cover the metal interconnects 19, 20 on the insulating layer 15, an insulating layer 15 is further formed.

Subsequently, after planarizing a surface of the insulating layer 15, the SOI substrate provided with the device is adhered to the adhered device part formation region of the support substrate including the adjacent device part 12 with the device facing the support substrate.

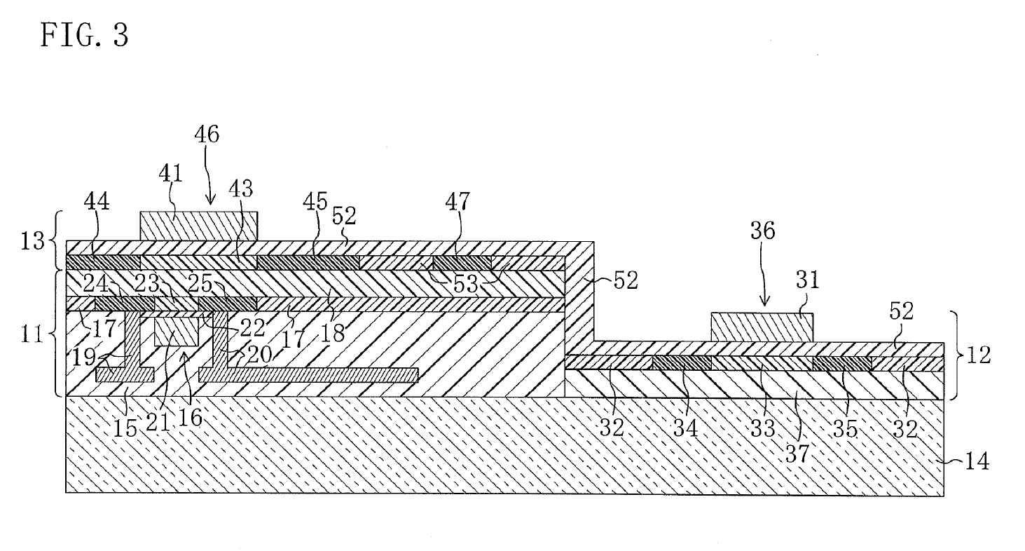

Next, a thermal process is performed to remove part of the substrate layer 49 along the hydrogen ion implantation region 42. Then, etching is performed to fabricate an adhered device part 11 as illustrated in FIG. 3.

(Multilayer Device Part Formation Process)

Next, the substrate layer 49 left to have a preferable thickness after the removal is used as a semiconductor layer to form a multilayer device part 13. That is, a mask is first formed on a portion of the semiconductor layer which corresponds to a position where a channel region is to be formed, and ions of an impurity element are implanted to form a channel region 43 in the semiconductor layer.

Subsequently, the mask is removed, and a gate insulating film 52 and a device isolation layer 53 are formed on the semiconductor layer. Then, a gate electrode 41 is patterned by photolithography on the gate insulating film 52 so that the gate electrode 41 corresponds to the channel region 43 under the gate insulating film 52. Impurity regions (a source region 44, a drain region 45, and a high concentration impurity region 47) are formed, thereby forming a TFT 46.

Next, as illustrated in FIG. 1, the TFT 46 and the TFT 36 of the adjacent device part 12 are covered with an interlayer insulating film 39.

Subsequently, contact holes reaching the source region 34 of the TFT 36, the source region 44, the drain region 45, and the high concentration impurity region 47 of the TFT 46, respectively are formed in the interlayer insulating film 39. Further, a contact hole extending from the interlayer insulating film 39 and reaching the metal interconnect 20 of the adhered device part 11 under the interlayer insulating film 39 is formed.

Next, a metal interconnect 40 is formed in the contact holes to be electrically connected to the source region 44 and the drain region 45 of the TFT 46, and the metal interconnect 20 of the adhered device part 11. Moreover, a metal interconnect 38 is formed in the contact hole to be electrically connected to the source region 34 of the TFT 36. Furthermore, the metal interconnects 40, 38 are patterned to extend on the interlayer insulating film 39, and to be electrically connected to each other. Note that the metal interconnects 40, 38 may be formed individually, and then electrically connected to each other, or may simultaneously be formed using the same material to be electrically connected to each other.

Next, to cover the metal interconnects 40, 38 on the interlayer insulating film 39, an interlayer insulating film 39 is further formed, thereby fabricating the multilayer device part 13. Thus, the semiconductor device 10 is completed. Note that here, the multilayer device part 13 and the adjacent device part 12 are individually formed, but the process of patterning a semiconductor layer such as the TFT 36 on the passivation film 37 of the adjacent device part 12, and the process of patterning a semiconductor layer such as the TFT 46 of the multilayer device part 13 may be performed simultaneously, and the gate insulating films 52, the gate electrodes 31, 41, and the impurity regions of the TFTs 36, 46 may also be formed simultaneously.

### Advantages of First Embodiment

According to the first embodiment, the multilayer device part 13 is stacked on the adhered device part 11 adhered to the support substrate 14, and the adjacent device part 12 is formed in a region adjacent to the adhered device part on the support substrate 14. Moreover, the adhered device part 11, the multilayer device part 13, and the adjacent device part 12 are electrically connected to one another. Therefore, the integration degree of the devices increases. For example, a low-voltage logic circuit, a stable analog circuit, a high-voltage drive circuit, etc. can be integrated at a high degree on a given substrate such as a glass substrate, a quartz substrate, or the like larger than a silicon substrate. As a result, it is possible to satisfactorily reduce the area of the semiconductor device 10.

Moreover, the support substrate 14 has an area larger than that of the adhered device part 11. Thus, it is possible to form the adjacent device part 12 having a property different from that of the adhered device part 11.

Moreover, the adjacent device part 12 is formed close to the adhered device part 11. Thus, the semiconductor device 10 including a plurality of device parts having different properties can be formed at a high integration degree while power loss caused by interconnects is reduced.

Moreover, since the device of the adhered device part 11 is adhered to the support substrate 14 while protected by the insulating layer (BOX layer 18), the adhered device part 11 can be configured as a high performance transistor, or the like.

Furthermore, the adhered device part 11 includes the active layer made of single crystal silicon or polysilicon in the TFT 16, so that the response speed of the TFT 16 increases.

Moreover, in the multilayer device part formation process, the substrate layer 49 remaining after the removal of part of the adhered substrate layer 49 is used as a semiconductor layer to form the multilayer device part 13, so that the manufacturing yield of the semiconductor device 10 increases.

### Second Embodiment

### Configuration of Semiconductor Device 60

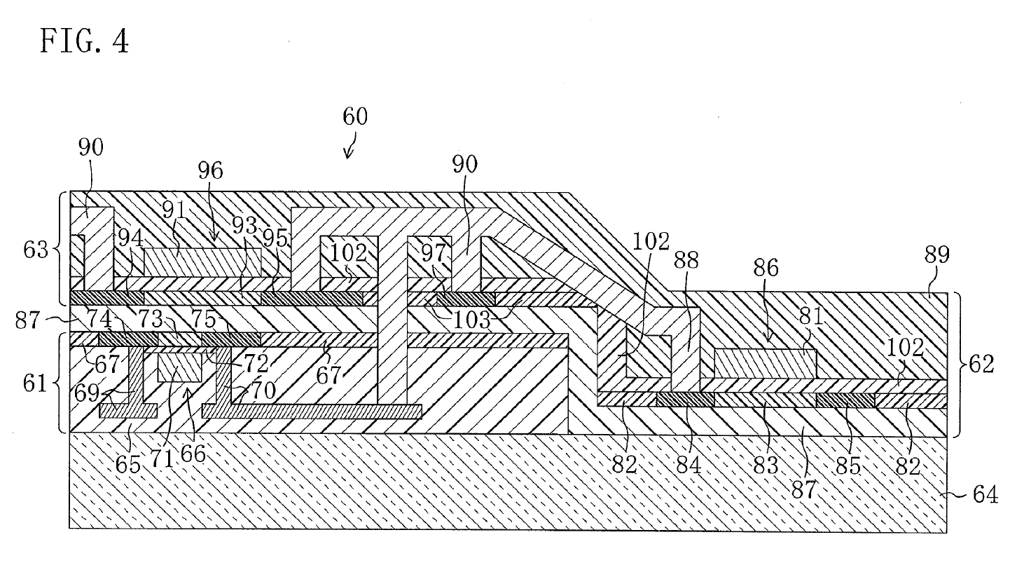

FIG. 4 is a cross-sectional view schematically illustrating main components of a semiconductor device 60 according to a second embodiment of the present invention. The semiconductor device 60 includes a support substrate 64, an adhered device part 61, a multilayer device part 63, and an adjacent device part 62.

The support substrate 64 is made of glass, quartz, plastic, or the like. Moreover, the support substrate 64 has an area larger than that of the adhered device part 61.

The adhered device part 61 is adhered on the support substrate 64. The adhered device part 61 includes an insulating layer 65 provided on the support substrate 64, and a TFT 66 provided on the insulating layer 65, thereby implementing a low-voltage circuit.

The TFT 66 includes an active layer, a gate insulating film 72 provided on the active layer, and a gate electrode 71 provided on the gate insulating film 72.

The active layer is made of single crystal silicon or polysilicon, and includes a channel region 73, a source region 74, and a drain region 75.

Metal interconnects 69, 70 are formed in the insulating layer 65. The metal interconnects 69, 70 are electrically connected to the source region 74 and the drain region 75, respectively of the TFT 66.

Moreover, a passivation film 87 is provided on the TFT 66 of the adhered device part 61.

The multilayer device part 63 is stacked on the passivation film 87 formed on the adhered device part 61. The multilayer device part 63 includes a TFT 96, and an interlayer insulating film 89 covering the TFT 96, thereby implementing a high-voltage circuit.

The TFT 96 includes an active layer, a gate insulating film 102 provided on the active layer, and a gate electrode 91 provided on the gate insulating film 102.

The active layer is made of single crystal silicon, polysilicon, or amorphous silicon, and includes a channel region 93, a source region 94, a drain region 95, and a high concentration impurity region 97.

A metal interconnect 90 electrically connected to the source region 94 and the drain region 95 of the TFT 96, and a metal interconnect 90 electrically connected to the high concentration impurity region 97 of the TFT 96 are formed in the interlayer insulating film 89. The metal interconnect 90 connected to the drain region 95 in the multilayer device part 63 reaches the metal interconnect 70 of the adhered device part 61 provided under the multilayer device part 63, and is electrically connected to the metal interconnect 70.

The adjacent device part 62 is formed in a region adjacent to the adhered device part on the support substrate 64. The adjacent device part 62 includes the passivation film 87 provided on the support substrate 64, a device isolation layer 82 and a TFT 86 provided on the passivation film 87, and the interlayer insulating film 89 covering the TFT 86, thereby implementing a high-voltage circuit. Moreover, the passivation film 87 on the support substrate 64 is formed such that the passivation film 87 provided on the adhered device part 61 passes along a side face of the adhered device part 61 to extend to the region adjacent to the adhered device part. Moreover, the adjacent device part 62 is formed close to the adhered device part 61.

The TFT 86 includes an active layer, a gate insulating film 102 provided on the active layer, and a gate electrode 81 provided on the gate insulating film 102.

The active layer is made of single crystal silicon, polysilicon, or amorphous silicon, and includes a channel region 83, a source region 84, and a drain region 85.

A metal interconnect 88 is formed in the interlayer insulating film 89. The metal interconnect 88 is electrically connected to the source region 84 and the drain region 85 of the TFT 86. The metal interconnect 88 of the adjacent device part 62 is electrically connected to the metal interconnect 70 of the adhered device part 61, and the metal interconnect 90 of the multilayer device part 63.

—Method for Manufacturing Semiconductor Device 60—

Next, a method for manufacturing the semiconductor device 60 according to the second embodiment of the present invention will be described.

(Adhered Device Part Formation Process)

First, a device which will be adhered to the support substrate 64 is fabricated. That is, an SOI substrate (silicon substrate) including an insulating layer, a semiconductor layer, and a substrate layer is first prepared as in the method illustrated in FIG. 2A of the first embodiment. The insulating layer is sandwiched between the semiconductor layer and the substrate layer. The semiconductor layer and the substrate layer each include a silicon layer.

Next, the semiconductor layer on the SOI substrate is patterned, and then, ions of an impurity element are implanted to form an active layer including a channel region 73.

Subsequently, a gate insulating film 72 and a device isolation layer 67 on the active layer are formed. Further, a gate electrode 71 is patterned on a region of the gate insulating film 72, the region corresponding to the channel region 73. Moreover, a source region 74 and a drain region 75 are formed by ion implantation, thereby forming a TFT 66.

Next, an insulating layer 65 is foamed on a side of the SOI substrate where the TFT 66 is provided. Subsequently, a mask is formed in a region on the insulating layer 65, the region corresponding to the active layer of the TFT 66.

Next, hydrogen ions are implanted into the SOI substrate from a side of the SOI substrate where the mask is provided on the insulating layer 65, thereby forming a hydrogen ion implantation region in the substrate layer.

Note that also in this case, as illustrated in FIG. 2B of the first embodiment, the hydrogen ion implantation region may be formed in the substrate layer without forming the mask. With this configuration, it is possible to simplify the process.

Subsequently, the mask is removed. Contact holes reaching the source region 74 and the drain region 75, respectively of the TFT 66 are formed in the insulating layer. Then, metal interconnects 69, 70 are formed in the contact holes. Moreover, the metal interconnects 69, 70 are patterned to extend on the insulating layer 65.

Next, to cover the metal interconnects 69, 70 on the insulating layer 65, an insulating layer 65 is further formed.

Subsequently, after planarizing a surface of the insulating layer 65, the SOI substrate provided with the device is adhered to the adhered device part formation region of the support substrate 64 with the device facing the support substrate 64.

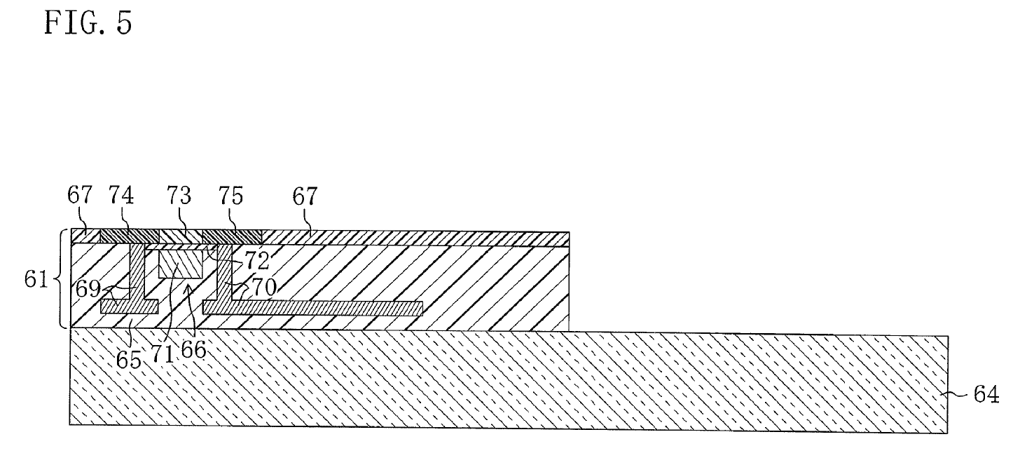

Next, a thermal process is performed to remove the substrate layer along the hydrogen ion implantation region, and then, the insulating layer provided under the substrate layer is removed by etching. Subsequently, the thickness of the semiconductor layer is adjusted to be, for example, about 10-500 nm, thereby forming the adhered device part 61 as illustrated in FIG. 5. Note that the adhered device part is made of the SOI substrate, but may be made of a silicon substrate. In this case, it is not necessary to remove the insulating layer provided under the substrate layer.

Next, a passivation film 87 is formed on the adhered device part 61 and a side surface of the adhered device part 61, and further, on the region where the adjacent device part is to be formed.

(Multilayer Device Part Formation Process)

Next, a multilayer device part 63 is formed on the adhered device part 61. That is, a semiconductor layer is first patterned on the passivation film 87 formed on the adhered device part 61.

Next, a mask is formed on a portion of the semiconductor layer which corresponds to a position where a channel region is to be formed, and ions of an impurity element are implanted to form a channel region 93 in the semiconductor layer.

Subsequently, the mask is removed, and a gate insulating film 102 is formed on the semiconductor layer. Then, a gate electrode 91 is patterned by photolithography on the gate insulating film 102 so that the gate electrode 91 corresponds to the channel region 93 under the gate insulating film 102. Impurity regions (a source region 94, a drain region 95, and a high concentration impurity region 97) are formed by ion implantation, thereby forming a TFT 96.

(Adjacent Device Part Formation Process)

Next, an adjacent device part 62 is formed in a region adjacent to the adhered device part 61 on the support substrate 64. That is, a semiconductor layer is patterned by photolithography on the passivation film 87 formed in the region adjacent to the adhered device part 61 on the support substrate 64.

Next, a mask is formed on a portion of the semiconductor layer which corresponds to a position where a channel region is to be formed, and ions of an impurity element are implanted to form a channel region 83 in the semiconductor layer.

Subsequently, the mask is removed, and a gate insulating film 102 is formed on the semiconductor layer. Then, a gate electrode 81 is patterned by photolithography on the gate insulating film 102 so that the gate electrode 81 corresponds to the channel region 83 under the gate insulating film 102. Impurity regions (a source region 84 and a drain region 85) are formed by ion implantation, thereby fabricating a TFT 86.

Next, as illustrated in FIG. 4, the TFT 96 of the multilayer device part 63 and the TFT 86 of the adjacent device part 62 are covered with an interlayer insulating film 89.

Subsequently, contact holes reaching the source regions 94, 84 and the drain regions 95, 85 of the TFT 96, 86, respectively are formed in the interlayer insulating film 89. Further, a contact hole extending from the interlayer insulating film 89 and reaching the metal interconnect 70 of the adhered device part 61 under the interlayer insulating film 89 is formed.

Next, a metal interconnect 90 is formed in the contact holes to be electrically connected to the source region 94, the drain region 95, and the high concentration impurity region 97 of the TFT 96, and the metal interconnect 70 of the adhered device part 61. Moreover, a metal interconnect 88 is formed in the contact hole to be electrically connected to the source region 84 of the TFT 86. Furthermore, the metal interconnects 90, 88 are patterned to extend on the interlayer insulating film 89, and to be electrically connected to each other. Note that the metal interconnects 90, 88 may be formed individually, and then electrically connected to each other, or may simultaneously be formed using the same material as an electrically connected one unit.

Next, to cover the metal interconnects 90, 88 on the interlayer insulating film 89, an interlayer insulating film 89 is further formed. Thus, the semiconductor device 60 is completed.

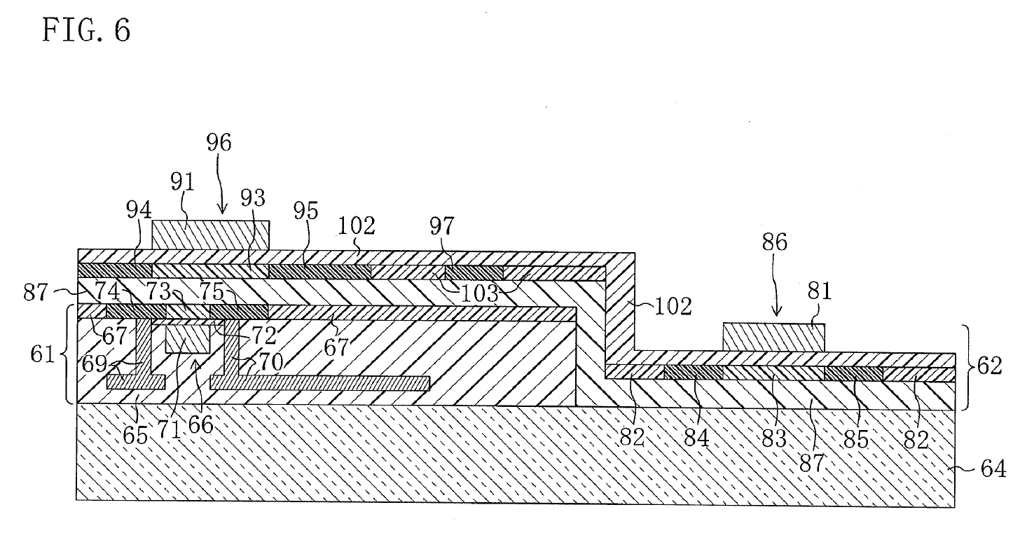

Note that the multilayer device part 63 and the adjacent device part 62 are individually fabricated in the above manufacturing method, but may be formed simultaneously. That is, as illustrated in FIG. 6, the adhered device part 61 is adhered to the support substrate 64, and the passivation film 87 is formed. Then, the semiconductor layers of the TFTs 96, 86 are simultaneously pattered, and are each subjected to ion implantation of impurities to form the active layers. Subsequently, formation of the gate insulating film 102, and patterning of the gate electrodes 91, 81 are simultaneously performed, and the drain and source regions are formed by ion implantation. The TFTs 96, 86 may thus be formed.

As described above, simultaneously fabricating the multilayer device part 63 and the adjacent device part 62 increases the manufacturing yield of the semiconductor device 60.

The fabrication of the multilayer device part 63 is not limited to the above method. The multilayer device part 63 may be fabricated by adhering an SOI substrate (a silicon substrate) including a device formed in a separate process as illustrated in FIGS. 2A and 2B of the first embodiment.

That is, for example, an SOI substrate including a device fabricated in a separate process is adhered onto the adhered device part 61. Then, at least part of a substrate layer of the SOI substrate is removed to form a lowermost device part (a first device part). Subsequently, the substrate layer remaining after the removal is used as at least a layer of semiconductor layers to form an upper device part (a second device part). The multilayer device part 63 including a plurality of device parts may thus be fabricated.

Alternatively, an SOI substrate or a silicon substrate including a device fabricated in a separate process is adhered onto the adhered device part 61. Then, a substrate layer and an insulating layer of the SOI substrate are removed, and a semiconductor layer of the SOI substrate or the silicon substrate is partially removed to adjust the thickness of the semiconductor layer. Subsequently, an insulating layer is formed to cover the device part. The multilayer device part 63 may thus be fabricated.

Alternatively, an SOI substrate including a device fabricated in a separate process is adhered onto the adhered device part 61. Then, a substrate layer and an insulating layer of the SOI substrate are removed. The multilayer device part 63 including the device formed in the SOI substrate may thus be fabricated.

### Advantages of Second Embodiment

According to the second embodiment, the multilayer device part 63 is stacked on the adhered device part 61 adhered to the support substrate 64, and the adjacent device part 62 is formed in a region adjacent to the adhered device part on the support substrate 64. Moreover, the adhered device part 61, the multilayer device part 63, and the adjacent device part 62 are electrically connected to one another. Therefore, the integration degree of the devices increases. For example, a low-voltage logic circuit, a stable analog circuit, a high-voltage drive circuit, etc. can be integrated at a high degree on a given substrate such as a glass substrate, a quartz substrate, or the like larger than a silicon substrate. As a result, it is possible to satisfactorily reduce the area of the semiconductor device 60.

Moreover, the support substrate 64 has an area larger than that of the adhered device part 61. Thus, it is possible to form the adjacent device part 62 having a property different from that of the adhered device part 61.

Moreover, the adjacent device part 62 is formed close to the adhered device part 61. Thus, the semiconductor device 60 including a plurality of device parts having different properties can be formed at a high integration degree while power loss caused by interconnects is reduced.

Furthermore, the adhered device part 61 includes the active layer made of single crystal silicon or polysilicon in the TFT 66, so that the response speed of the TFT 66 increases.

Further, the multilayer device part 63 and the adjacent device part 62 include the active layers made of single crystal silicon, polysilicon, or amorphous silicon in the TFTs 96, 86, respectively, so that the response speed of the TFTs 96, 86 increases.

Moreover, devices previously fabricated in SOI substrates or silicon substrates are adhered onto the support substrate 64 and the adhered device part 61, and then excess silicon layers are removed to adjust the thickness of the silicon layers. Therefore, it is possible to efficiently form the silicon layers having preferable thicknesses. Furthermore, at that time, adjusting the thickness of the silicon layer to be about 10-500 nm further increases the response property of each TFT.

Further, fabricating the multilayer device part 63 by adhering a SOI substrate formed in a separate process onto the adhered device part 61 makes it possible to easily achieve, for example, miniaturization of the device of the multilayer device part 63. Moreover, repeating such an adhesion process can easily form a plurality of devices in the multilayer device part 63, thereby allowing the area of the semiconductor device 60 to be reduced satisfactorily.

### Third Embodiment

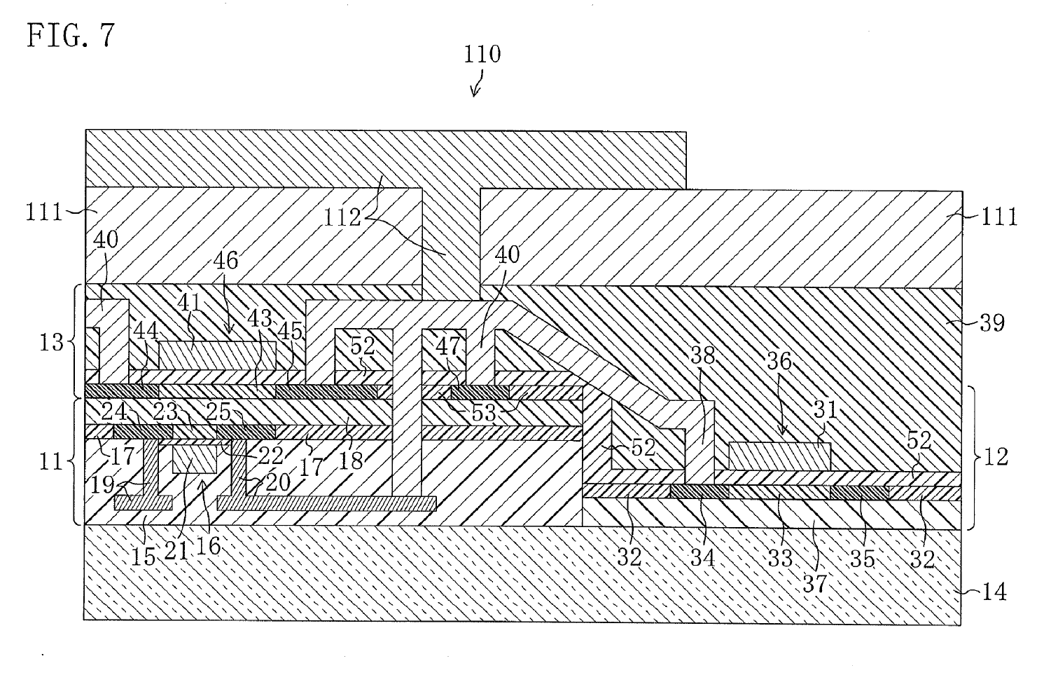

FIG. 7 is a cross-sectional view schematically illustrating main components of a display device 110 according to a third embodiment of the present invention. The display device 110 has a configuration in which a planarizing film 111, a display electrode 112 formed in an active matrix region, etc. are provided on the semiconductor device 10 illustrated in the first embodiment. In the third embodiment, the display electrode 110 is electrically connected to the metal interconnect 40 of the multilayer device part 13 and the metal interconnect 38 electrically connected to the source region 34 of the adjacent device part 12. That is, the multilayer device part 13 is at least a part of the active matrix region.

The display electrode forms a lower electrode for liquid crystal display when the display device 110 is a liquid crystal display device including a liquid crystal display region provided in the active matrix region. Alternatively, the display electrode forms an EL lower or upper electrode when the display device 110 is an organic EL display device or an inorganic EL display device including an EL display region provided in the active matrix region.

### Advantages of Third Embodiment

According to the third embodiment, it is possible to provide the display device 110 having advantages such as an increase in integration degree of the devices, which satisfactorily reduces the area as in the first embodiment.

### Fourth Embodiment

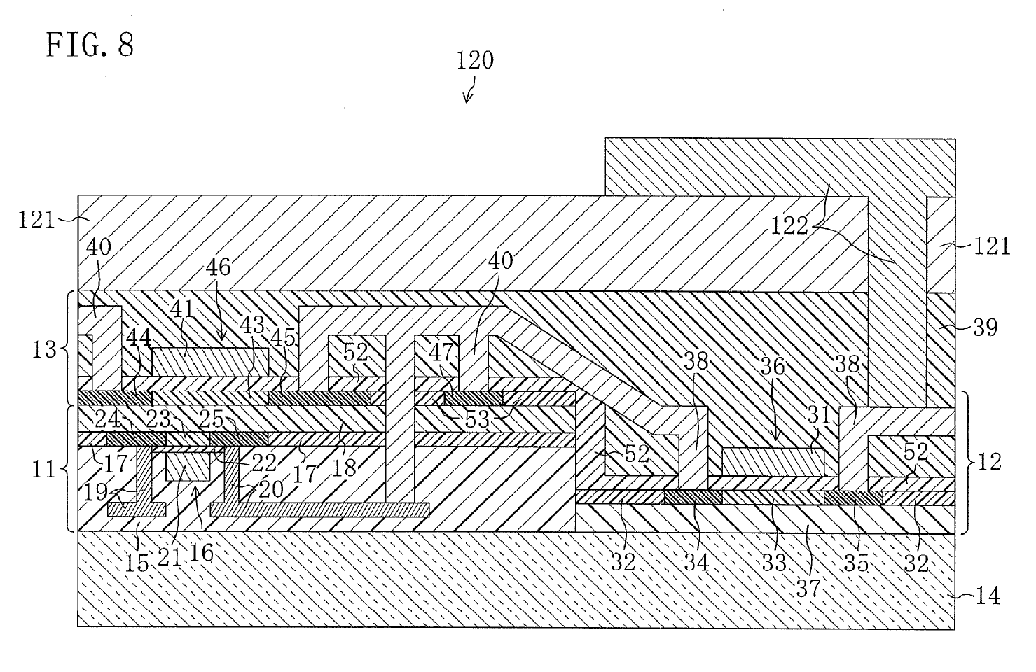

FIG. 8 is a cross-sectional view schematically illustrating main components of a display device 120 according to a fourth embodiment of the present invention. The display device 120 has a configuration in which a planarization layer 121, a display electrode 122 formed in an active matrix region, etc. are provided on the semiconductor device 10 illustrated in the first embodiment. Here, the semiconductor device used in the display device 120 is provided with a metal interconnect 38 electrically connected to the drain region 35 of the adjacent device part 12 in the semiconductor device 10 illustrated in the first embodiment.

The display electrode is electrically connected to the metal interconnect 38 electrically connected to the drain region 35 of the adjacent device part 12. That is, the adjacent device part 12 is at least a part of the active matrix region.

The display electrode forms a lower electrode for liquid crystal display when the display device 120 is a liquid crystal display device including a liquid crystal display region provided in the active matrix region. Alternatively, the display electrode forms an EL lower or upper electrode when the display device 120 is an organic EL display device or an inorganic EL display device including an EL display region provided in the active matrix region.

### Advantages of Fourth Embodiment

According to the fourth embodiment, it is possible to provide the display device 120 having advantages such as an increase in integration degree of the devices, which satisfactorily reduces the area as in the first embodiment.

Note that any component provided to be adjacent to the adhered device part and including a semiconductor element may be used as the adjacent device part in the first and second embodiments of the present invention. For example, when an adhered device part and a multilayer device part are used as semiconductor elements of an active matrix region of a display device, the adjacent device part may be, for example, a drive circuit in the above active matrix region, a high performance device, or the like necessary for integration of systems requiring higher performance such as memories, microprocessors, image processors, timing controllers, etc. In contrast, the adjacent device part may be used as a semiconductor element of an active matrix region of a display device. In this case, the adhered device part and the multilayer device part implement a peripheral circuit such as the drive circuit in the above active matrix region.

Moreover, the display devices 110, 120 according to the third and fourth embodiments of the present invention each are not limited to a liquid crystal display device, an organic EL display device, or an inorganic EL display device. For example, the display devices 110, 120 may be display devices including plasma displays, plasma address liquid crystal displays, field emission displays, surface-conduction electron-emitter displays, etc.

### INDUSTRIAL APPLICABILITY

As described above, the present invention is useful for semiconductor devices and methods for manufacturing the same.

1. A semiconductor device comprising:
a support substrate;
an adhered device part adhered to the support substrate;
a multilayer device part stacked on the adhered device part; and
an adjacent device part formed in a region adjacent to the adhered device part on the support substrate, wherein
the adhered device part, the multilayer device part, and the adjacent device part are electrically connected to one another.

2. The semiconductor device of claim 1, wherein
the support substrate has an area larger than that of the adhered device part.

3. The semiconductor device of claim 1, wherein
the adjacent device part is formed close to the adhered device part.

4. The semiconductor device of claim 1, wherein
the support substrate is made of glass, quartz, or plastic.

5. The semiconductor device of claim 4, wherein
the adjacent device part is made of polysilicon or amorphous silicon.

6. The semiconductor device of claim 1, wherein
the adhered device part is made of single crystal silicon or polysilicon.

7. The semiconductor device of claim 1, wherein
the multilayer device part is made of single crystal silicon, polysilicon, or amorphous silicon.

8. The semiconductor device of claim 1, wherein
the adhered device part includes a BOX layer, and
the adhered device part and the multilayer device part are isolated from each other by the BOX layer.

9. The semiconductor device of claim 1, further comprising:
an active matrix region, wherein
the multilayer device part or the adjacent device part is at least a part of the active matrix region.

10. The semiconductor device of claim 1, further comprising:
an active matrix region, wherein
the multilayer device part or the adjacent device part is at least a part of a drive circuit in the active matrix region.

11. The semiconductor device of claim 9, wherein
the active matrix region includes a liquid crystal display region or an EL display region.

12. A method for manufacturing a semiconductor device comprising:
a device formation process for forming a device in an SOI substrate including an insulating layer, a semiconductor layer, and a substrate layer, the insulating layer being sandwiched between the semiconductor layer and the substrate layer, and the device including the semiconductor layer;
an adjacent device part formation process for forming an adjacent device part on a support substrate;
a process for forming a hydrogen ion implantation region in the substrate layer;
an adhesion process for adhering the SOI substrate provided with the device to the support substrate provided with the adjacent device part such that the device faces the support substrate;
an adhered device part formation process for forming an adhered device part including the device by removing at least part of the substrate layer from the SOI substrate adhered to the support substrate by a thermal process along the hydrogen ion implantation region, and then by performing an etching process;
a multilayer device part formation process for forming a multilayer device part by using the substrate layer remaining after the removal as at least a layer of semiconductor layers; and
a connection process for electrically connecting the adjacent device part, the adhered device part, and the multilayer device part to one another.

13. A method for manufacturing a semiconductor device, comprising:
a device formation process for forming a device in an SOI substrate including an insulating layer, a semiconductor layer, and a substrate layer, the insulating layer being sandwiched between the semiconductor layer and the substrate layer, and the device including the semiconductor layer;
a process for forming a hydrogen ion implantation region in the substrate layer;
an adhesion process for adhering the SOI substrate provided with the device to a support substrate such that the device faces the support substrate;
an adhered device part formation process for forming an adhered device part including the device by removing the substrate layer from the SOI substrate adhered to the support substrate by a thermal process along the hydrogen ion implantation region, and then by performing an etching process;
a multilayer device part formation process for forming a multilayer device part on the adhered device part;
an adjacent device part formation process for forming an adjacent device part on the support substrate such that the adjacent device part is adjacent to the adhered device part; and
a connection process for electrically connecting the adjacent device part, the adhered device part, and the multilayer device part to one another.

14. A method for manufacturing a semiconductor device, comprising:
a device formation process for forming a device in a silicon substrate including a semiconductor layer and a substrate layer;
a process for forming a hydrogen ion implantation region in the substrate layer;
an adhesion process for adhering the silicon substrate provided with the device to a support substrate such that the device faces the support substrate;
an adhered device part formation process for forming an adhered device part by removing an excess silicon layer from the silicon substrate adhered to the support substrate by a thermal process along the hydrogen ion implantation region, and then by performing an etching process to adjust a thickness of the silicon layer in a region provided with the device;
a multilayer device part formation process for forming an insulating layer covering the silicon substrate, and forming an multilayer device part on the insulating layer;
an adjacent device part formation process for forming an adjacent device part on the support substrate such that the adjacent device part is adjacent to the adhered device part; and
a connection process for electrically connecting the adjacent device part, the adhered device part, and the multilayer device part to one another.

15. The method of claim 14, wherein
the silicon layer is adjusted to have a thickness of 10-500 nm in the adhered device part formation process.

16. The semiconductor device of claim 10, wherein
the active matrix region includes a liquid crystal display region or an EL display region.
